(19) United States
(12) Patent Application Publication
(10) Pub. No.: US 2016/0017494 A1
(43) Pub. Date: Jan. 21, 2016

(54) APPARATUS AND METHOD FOR TUNING A PLASMA PROFILE USING A TUNING RING IN A PROCESSING CHAMBER

(71) Applicant: APPLIED MATERIALS, INC., Santa Clara, CA (US)

(72) Inventors: Mohamad A. AYOUB, Los Gatos, CA (US); Jian J. CHEN, Fremont, CA (US)

(21) Appl. No.: 14/772,228

(22) PCT Filed: Feb. 12, 2014
(86) PCT No.: PCT/US2014/016107

§ 371 Date: Sep. 2, 2015

Related U.S. Application Data
(60) Provisional application No. 61/792,255, filed on Mar. 15, 2013.

(51) Int. Cl. C23C 16/505; C23C 16/52; C23C 16/458

(52) U.S. Cl. CPC C23C 16/505; C23C 16/458; C23C 16/52

(57) ABSTRACT

Embodiments of the present invention relate to apparatus for improving a plasma profile during plasma processing of a substrate. According to embodiments, the apparatus includes a tuning ring electrically coupled to a variable capacitor. The capacitance is controlled to control the RF and resulting plasma coupling to the tuning ring. The plasma profile and the resulting deposition film thickness across the substrate are correspondingly controlled by adjusting the capacitance and impedance at the tuning ring.

### BACKGROUND OF THE INVENTION

1. Field of the Invention

Embodiments of the present invention generally relate to an apparatus and method for processing substrates. More particularly, embodiments of the present invention relate to a plasma processing chamber with a tuning ring for improved center to edge plasma profile uniformity.

2. Description of the Related Art

Plasma processing, such as plasma enhanced chemical vapor deposition (PECVD), is used to deposit materials, such as blanket dielectric films on substrates, such as semiconductor wafers. A challenge for current plasma processing chambers and processes includes controlling critical dimension uniformity during plasma deposition processes. A particular challenge includes substrate center to edge thickness uniformity in films deposited using current plasma processing chambers and techniques.

Accordingly, it is desirable to develop an apparatus and process for improving the center to edge thickness uniformity of films deposited during plasma processing.

### SUMMARY OF THE INVENTION

In one embodiment of the present invention, a plasma processing apparatus comprises a chamber body and a powered gas distribution manifold enclosing a process volume, a pedestal disposed in the process volume for supporting a substrate, and a conductive tuning ring disposed between the chamber body and the powered gas distribution manifold.

In another embodiment, a method for processing a substrate comprises powering a gas distribution manifold using an RF source while flowing one or more process gases into a plasma chamber to form a plasma within a process volume of the chamber and controlling the plasma by varying a capacitance of a conductive tuning ring disposed between the powered gas distribution manifold and a chamber body of the chamber.

In yet another embodiment, a tuning ring assembly for use in a plasma processing apparatus comprises a conductive tuning ring and a variable capacitor electrically coupled to the conductive tuning ring.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic, cross-sectional view of a plasma processing apparatus according to one embodiment of the present invention.

FIGS. 2A-2D are exemplary depictions of the electric field magnitude distribution across a substrate according to varying capacitances applied to the tuning ring in the chamber of FIG. 1.

FIGS. 3A-3D are exemplary depictions of the resulting film thickness distribution across a substrate, processed in the chamber of FIG. 1, using varying capacitances applied to the tuning ring during plasma deposition processing.

FIGS. 4A-4D are additional exemplary depictions of the resulting film thickness distribution across a substrate, processed in the chamber of FIG. 1, using varying capacitances applied to the tuning ring during plasma deposition processing.

### DETAILED DESCRIPTION

Embodiments of the present invention relate to apparatus for improving a plasma profile during plasma processing of a substrate. According to embodiments, the apparatus includes a tuning ring electrically coupled to a variable capacitor. The capacitance is controlled to control the RF and resulting plasma coupling to the tuning ring. The plasma profile and the resulting deposition film thickness across the substrate are correspondingly controlled by adjusting the capacitance and impedance at the tuning ring.

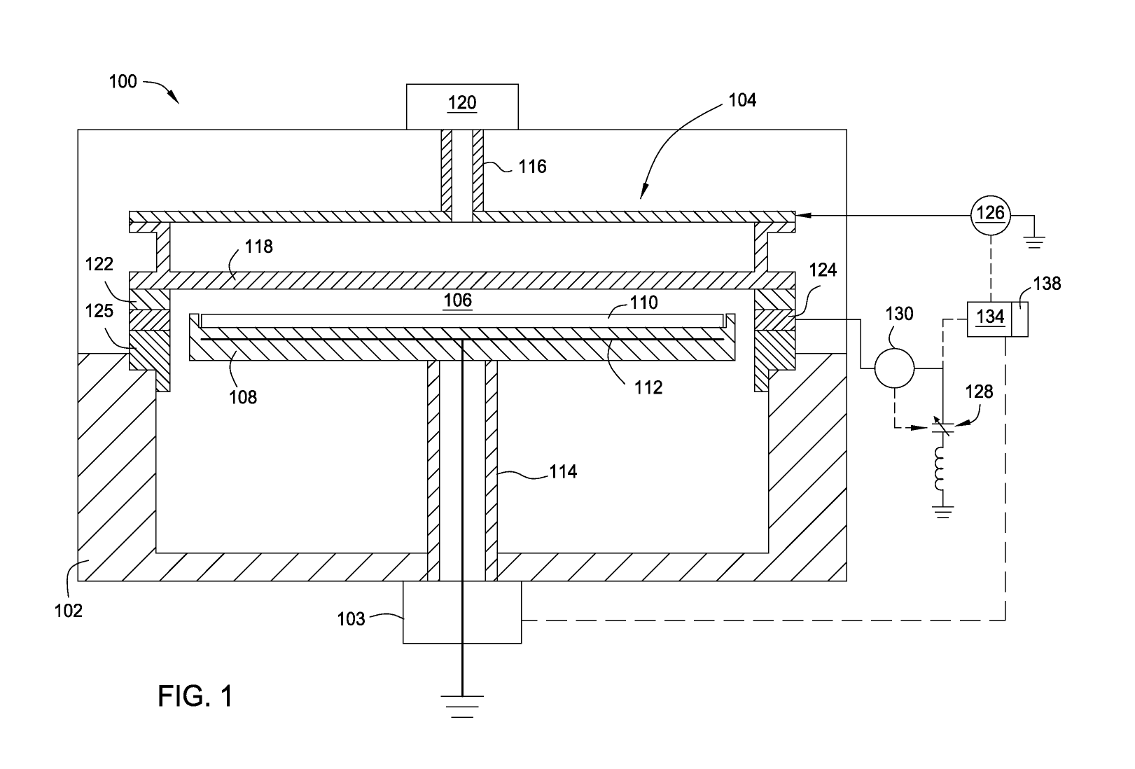

FIG. 1 is a schematic, cross-sectional view of a plasma processing apparatus according to one embodiment of the present invention. The apparatus includes a chamber 100 in which one or more films may be deposited on a substrate 110. The chamber includes a chamber body 102 and a gas distribution assembly 104, which distributes gases uniformly into a process volume 106. A pedestal 108 is disposed within the process volume and supports the substrate 110. The pedestal 108 includes a heating element (not shown) and an electrode 112. The pedestal 108 is movably disposed in the process volume by a stem 114 that extends through the chamber body 102, where it is connected to a drive system 103 for raising, lowering, and/or rotating the pedestal 108.

The gas distribution assembly 104 includes a gas inlet passage 116, which delivers gas from a gas flow controller 120 into a gas distribution manifold 118. The gas distribution manifold 118 includes a plurality of nozzles (not shown) through which gaseous mixtures are injected during processing.

An RF (radio frequency) power source 126 provides a electromagnetic energy to power the gas distribution manifold 118, which acts as a powered electrode, to facilitate generation of a plasma between the gas distribution manifold 118 and the pedestal 108. The pedestal 108 includes an electrode 112, which is electrically grounded such that an electric field is generated in the chamber 100 between the powered gas distribution manifold 118 and the electrode 112.

A ceramic ring 122 is positioned below the gas distribution manifold 118. A tuning ring 124 is disposed between the ceramic ring 122 and an isolator 125, which isolates the tuning ring 124 from the chamber body 102. The tuning ring 124 is made from a conductive material, such as aluminum. As depicted in FIG. 1, the tuning ring 124 is positioned concentrically about the pedestal 108 and substrate 110 during processing of the substrate 110. The tuning ring 124 is electrically coupled to a variable capacitor 128, such as a variable vacuum capacitor, and terminated to ground. In addition, a sensor 130, such as a VI sensor, is positioned between the tuning ring 124 and the variable capacitor 128 for use in controlling the current flow through the tuning ring 124 and the variable capacitor 128. A system controller 134 controls the functions of the various components, such as the RF power source 126, the drive system 103, and the variable capacitor 128. The system controller 134 executes system control software stored in a memory 138.

Thus, an additional RF path is established between the powered gas distribution manifold 118 and the tuning ring 124. Further, by changing the capacitance of the variable capacitor 128, the impedance for the RF path through the tuning ring 124 changes, in turn, causing a change in the RF field coupled to the tuning ring 124. For example, a maximum current and corresponding minimum impedance of the tuning ring 124 can be achieved by varying the total capacitance of the variable capacitor 128. Therefore, the plasma in the process volume 106 may be modulated across the surface of the substrate 110 during plasma processing.

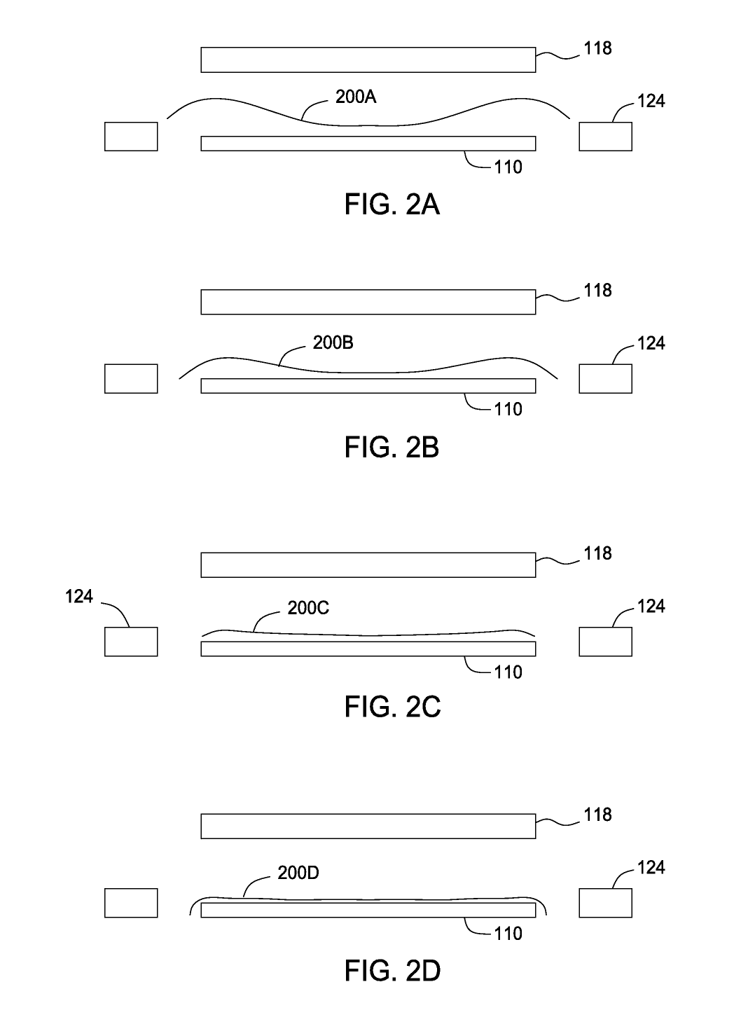

FIGS. 2A-2D are exemplary depictions of the electric field magnitude distribution across the substrate 110 according to varying capacitances applied to the tuning ring 124 in the chamber 100 of FIG. 1. FIG. 2A depicts the electric field distribution 200A across the substrate 110 with the tuning ring 124 connected to ground (i.e., minimal impedance or equivalent to infinite capacitance). As can be seen from this example, the electric field is significantly increased at the edge of the substrate 110 (i.e., edge high) due to the high electrical coupling between the RF generated at the powered gas distribution manifold 118 and the tuning ring 124.

FIG. 2B depicts the electric field distribution 200B across the substrate 110 with a capacitance between about 1200 pF and about 2000 pF at the variable capacitor 128 coupled to the tuning ring 124. As can be seen from this example, the electric field is lowered at the edge of the substrate 110 as compared to the example in FIG. 2A because the capacitance is lowered and the impedance to the tuning ring 124 is increased.

FIG. 2C depicts the electric field distribution 200C across the substrate 110 with a capacitance between about 500 pF and about 800 pF at the variable capacitor 128 coupled to the tuning ring 124. As can be seen from this example, by further decreasing the capacitance in the variable capacitor 128 (i.e., increasing impedance), the electric field is further lowered at the edge of the substrate 110 as compared to the example in FIG. 2B.

FIG. 2D depicts the electric field distribution 200D across the substrate 110 with the tuning ring 124 disconnected and electrically isolated (i.e., infinite impedance). As can be seen from this example, the electric field is significantly lowered (i.e., edge drop) at the edge of the substrate 110 due to the electric isolation between the RF generated at the powered gas distribution manifold 118 and the tuning ring 124.

From the examples shown in FIGS. 2A-2D, it is clear that varying the capacitance in the variable capacitor 128 electrically coupled to the tuning ring 124 results in a corresponding variation in the electric field across the surface of the substrate 110. In particular, increasing the capacitance in the variable capacitor 128, and the corresponding decrease in the impedance through the tuning ring 124, results in an increased magnitude of the electric field at the edge of the substrate 110 being processed due to the RF coupling between the powered gas distribution manifold 118 and the tuning ring 124. Further, since the electric field is the power driver for generating the plasma in the chamber 100, it follows that increasing the magnitude of the electric field at the edge of the substrate 110 also increases the plasma density at the edge of the substrate 110 due to increased coupling of the plasma to the tuning ring 124. As a result, not only is the electric field across the surface of the substrate 110 being processed varied, but the plasma profile across the surface of the substrate 110 is correspondingly varied by varying the capacitance in the variable capacitor 128 electrically coupled to the tuning ring 124. Correspondingly, the resulting film thickness profile deposited on the substrate 110 correlates with the plasma profile, resulting in the capability of varying the deposition film thickness profile by varying the capacitance in the variable capacitor 128 electrically coupled to the tuning ring 124.

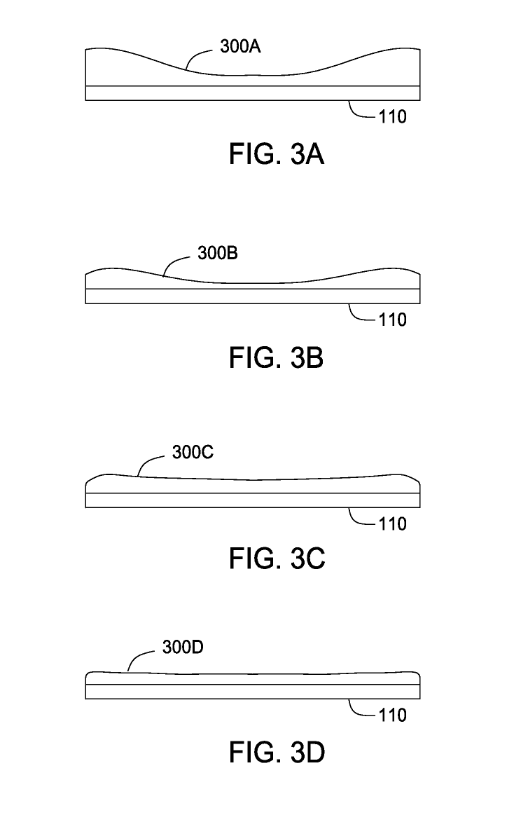

FIGS. 3A-3D are exemplary depictions of the resulting film thickness distribution across the substrate 110, processed in the chamber 100, using varying capacitances applied to the tuning ring 124 during plasma deposition processing. FIG. 3A depicts the film thickness distribution across the substrate 110 with the variable capacitor 128 set at 10% of its maximum capacitance (i.e., high impedance). As can be seen from this example, the film thickness 300A is naturally high at the edge of the substrate 110 (i.e., edge high) and naturally low at the center of the substrate 110 (i.e., center low) due to the natural plasma processing conditions in the chamber 100 (e.g., plasma hump at edge of substrate).

FIG. 3B depicts the film thickness distribution across the substrate 110 with the variable capacitor 128 set at 25% of its maximum capacitance. As can be seen from this example, by increasing the capacitance in the variable capacitor 128 (i.e., decreasing impedance), the film thickness 300B is lowered at the edge of the substrate 110 and the film thickness is raised at the center of the substrate 110 as compared to the example in FIG. 3A, as if the thickness profile behaved like an s-shaped string, and the two ends of the string were pulled outwardly when increasing the capacitance.

FIG. 3C depicts the film thickness distribution across the substrate 110 with the variable capacitor 128 set at 35% of its maximum capacitance. As can be seen from this example, by increasing the capacitance in the variable capacitor 128 (i.e., decreasing impedance), the film thickness 300C is lowered at the edge of the substrate 110 and the film thickness is raised at the center of the substrate 110 as compared to the example in FIG. 3B.

FIG. 3D depicts the film thickness distribution across the substrate 110 with the variable capacitor 128 set at 50% of its maximum capacitance. As can be seen from this example, by increasing the capacitance in the variable capacitor 128 (i.e., decreasing impedance), the film thickness 300D is further lowered at the edge of the substrate 110 and the film thickness is further raised at the center of the substrate 110 as compared to the example in FIG. 3C.

From the examples shown in FIGS. 3A-3D, it is clear that varying the capacitance in the variable capacitor 128 electrically coupled to the tuning ring 124 results in a corresponding variation in the deposited film thickness across the surface of the substrate 110. In particular, increasing the capacitance in the variable capacitor 128, and correspondingly decreasing the impedance at the tuning ring 124, results in a decrease in the corresponding edge film thickness and an increase in the corresponding center film thickness of the substrate 110 for a process that is naturally results in an edge-high and center-thin film thickness profile. This is because, as shown in FIGS. 2A-2D, by increasing the tuning capacitance, the electric field to the tuning ring 124 is stronger, leading to more plasma coupling to the tuning ring 124. Thus, for a process that naturally results in a “plasma hump” around the edge of the substrate 110, increasing the tuning capacitance in the tuning ring 124 pulls the “plasma hump” toward the tuning ring 124 and away from the edge of the substrate 110. This results in the plasma profile being “stretched out”, such that the resulting film thickness around the edge of the substrate is lowered and the thickness in the center of the substrate 110 is raised (as if the thickness profile behaved like an s-shaped string, and the two ends of the string were pulled outwardly) thereby improving film deposition uniformity.

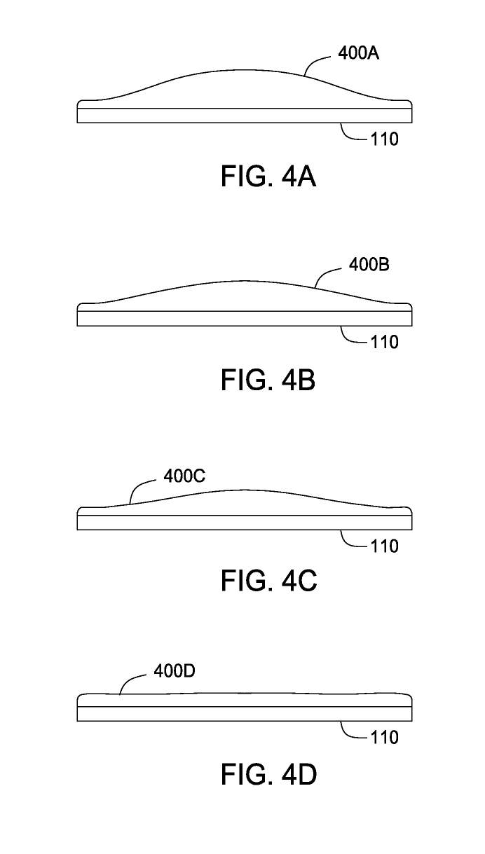

FIGS. 4A-4D are additional exemplary depictions of the resulting film thickness distribution across the substrate 110, processed in the chamber 100, using varying capacitances applied to the tuning ring 124 during plasma deposition processing. FIG. 4A depicts the film thickness distribution across the substrate 110 with the variable capacitor 128 set at 10% of its maximum capacitance (i.e., high impedance). As can be seen from this example, the film thickness 400A is naturally low at the edge of the substrate 110 (i.e., edge thin) and naturally high at the center of the substrate 110 (i.e., center high) due to the natural plasma processing conditions in the chamber 100.

FIG. 4B depicts the film thickness distribution across the substrate 110 with the variable capacitor 128 set at 25% of its maximum capacitance. As can be seen from this example, by increasing the capacitance in the variable capacitor 128 (i.e., decreasing impedance), the film thickness 400B is raised at the edge of the substrate 110 and the film thickness 400B is lowered at the center of the substrate 110 as compared to the example in FIG. 4A, as if the thickness profile behaved like an s-shaped string, and the two ends of the string were pulled outwardly.

FIG. 4C depicts the film thickness distribution across the substrate 110 with the variable capacitor 128 set at 35% of its maximum capacitance. As can be seen from this example, by increasing the capacitance in the variable capacitor 128 (i.e., decreasing impedance), the film thickness 400C is raised at the edge of the substrate 110 and the film thickness 400C is lowered at the center of the substrate as compared to the example in FIG. 4B.

FIG. 4D depicts the film thickness distribution across the substrate 110 with the variable capacitor 128 set at 50% of its maximum capacitance. As can be seen from this example, by increasing the capacitance in the variable capacitor 128 (i.e., decreasing impedance), the film thickness 400D is further raised at the edge of the substrate 110 and the film thickness is further lowered at the center of the substrate 110 as compared to the example in FIG. 4C.

From the examples shown in FIGS. 4A-4D, it is clear that varying the capacitance in the variable capacitor 128 electrically coupled to the tuning ring 124 results in a corresponding variation in the deposited film thickness across the surface of the substrate 110. In particular, increasing the capacitance in the variable capacitor 128, and correspondingly decreasing the impedance at the tuning ring 124, results in an increase in the corresponding edge film thickness and a decrease in the corresponding center film thickness of the substrate 110 for a process that is naturally results in an edge-thin and center-high film thickness profile. This is because, as shown in FIGS. 2A-2D, by increasing the tuning capacitance, the electric field to the tuning ring 124 is stronger, leading to more plasma coupling to the tuning ring 124. Thus, for a process that naturally results in low plasma density around the edge of the substrate 110, increasing the tuning capacitance in the tuning ring 124 pulls the plasma toward the tuning ring 124 and from the center of the substrate 110 toward the edge of the substrate 110. This results in the plasma profile being “stretched out”, such that the resulting film thickness around the edge of the substrate 110 is raised and the thickness in the center of the substrate 110 is lowered thereby improving film deposition uniformity.

While the foregoing is directed to embodiments of the present invention, other and further embodiments of the invention may be devised without departing from the basic scope thereof, and the scope thereof is determined by the claims that follow.

1. A plasma processing apparatus, comprising:
a chamber body and a powered gas distribution manifold enclosing a process volume;
a pedestal disposed in the process volume for supporting a substrate; and
a conductive tuning ring disposed between the chamber body and the powered gas distribution manifold.

2. The plasma processing apparatus of claim 1, wherein the conductive tuning ring is electrically coupled to a variable capacitor.

3. (canceled)

4. The plasma processing apparatus of claim 2, wherein the variable capacitor is coupled to a sensor and a controller configured to control the capacitance of the variable capacitor.

5. The plasma processing apparatus of claim 2, wherein the variable capacitor is coupled to a sensor and a controller configured to control the current flowing through the variable capacitor.

6. The plasma processing apparatus of claim 2, wherein the conductive tuning ring comprises aluminum.

7. The plasma processing apparatus of claim 2, further comprising a drive system for raising the pedestal such that the conductive tuning ring is concentric about a substrate supported by the pedestal.

8. The plasma processing apparatus of claim 2, wherein the variable capacitor is a variable vacuum capacitor.

9. A method for processing a substrate, comprising:
powering a gas distribution manifold using an RF source while flowing one or more process gases into a plasma chamber to form a plasma within a process volume of the chamber; and
controlling the plasma by varying a capacitance of a conductive tuning ring disposed between the powered gas distribution manifold and a chamber body of the chamber.

10. The method of claim 9, further comprising controlling an impedance to the conductive tuning ring by varying the capacitance of the conductive tuning ring.

11. The method of claim 9, further comprising controlling a current to the conductive tuning ring by varying the capacitance of the conductive tuning ring.

12. The method of claim 9, further comprising:
positioning a substrate within the process volume using a substrate support pedestal.

13. The method of claim 12, further comprising:
decreasing the plasma density at the edge of the substrate by increasing the capacitance of the variable capacitor.

14. A tuning ring assembly for use in a plasma processing apparatus, comprising:
a conductive tuning ring; and
a variable capacitor electrically coupled to the conductive tuning ring.

15. The tuning ring assembly of claim 14, further comprising a sensor coupled to the conductive tuning ring.

16. The tuning ring assembly of claim 15, wherein the conductive tuning ring comprises aluminum.

17. The plasma processing apparatus of claim 1, further comprising a ceramic ring disposed between the powered gas distribution manifold and the tuning ring.

18. The plasma processing apparatus of claim 17, wherein the conductive tuning ring is electrically isolated from the chamber body.

19. The method of claim 10, further comprising controlling an impedance to the conductive tuning ring to a minimum value by varying the capacitance of the conductive tuning ring.

20. The method of claim 11, further comprising controlling a current to the conductive tuning ring to a maximum value by varying the capacitance of the conductive tuning ring.

21. The method of claim 12, further comprising:
increasing the plasma density at the edge of the substrate by increasing the capacitance of the variable capacitor.
